(19) United States
(12) Patent Application Publication
(10) Pub. No.: US 2017/0256635 A1
(43) Pub. Date: Sep. 7, 2017

(54) NITRIDE SEMICONDUCTOR AND NITRIDE SEMICONDUCTOR MANUFACTURING METHOD

(71) Applicant: SHARP KABUSHIKI KAISHA, Sakai City, Osaka (JP)

(72) Inventors: Atsushi OGAWA, Sakai City, Osaka (JP); Manabu TOHSAKI, Sakai City, Osaka (JP); Mai OKAZAKI, Osaka (JP); Yohsuke FUJISHIGE, Osaka (JP); Masayuki TAJIRI, Osaka (JP); Nobuyuki ITO, Osaka (JP)

(73) Assignee: SHARP KABUSHIKI KAISHA, Sakai City, Osaka (JP)

(21) Appl. No.: 15/506,670

(22) PCT Filed: Jun. 3, 2015
(86) PCT No.: PCT/JP2015/066092

§ 371 Date: Feb. 24, 2017

(30) Foreign Application Priority Data
Aug. 27, 2014 (JP) 2014-173176

(51) Int. Cl. H01L 29/778; H01L 29/66; H01L 21/02

(52) U.S. Cl. CPC H01L 29/7783; H01L 21/02381; H01L 21/0254; H01L 29/66462

(57) ABSTRACT

In a nitride semiconductor including a Si substrate and a nitride semiconductor stacked body disposed on the Si substrate, the half value width of an X-ray diffraction rocking curve of the Si substrate is less than 160 arcsec.

### TECHNICAL FIELD

The present invention relates to a nitride semiconductor and to a method for manufacturing the nitride semiconductor.

### BACKGROUND ART

Nitride semiconductors are represented by the general formula InₓAl_{y}Ga_{1-x-y}N (0≦x≦1, 0≦y≦1, and 0≦x+y≦1). The band gaps of these nitride semiconductors can be changed within the range of 1.95 eV to 6 eV by changing their composition. Therefore, research and development aimed at using the nitride semiconductors as the materials of light-emitting devices in a wide wavelength range from ultraviolet to infrared is being conducted, and such materials have been put into practical use.

Control devices using nitride semiconductors are used as, for example, power elements that operate at high frequency and high power. In particular, known examples of control devices suitable for amplification in a high-frequency band include FETs such as high electron mobility transistors (HEMTs).

Examples of conventional control devices using nitride semiconductors include a device described in PTL 1 (Japanese Patent No. 5407385). This conventional nitride semiconductor device includes: a composite substrate including a substrate, a nitride semiconductor layer laminated onto the substrate, and a bonding layer disposed between the substrate and the nitride semiconductor layer; and a nitride semiconductor stacked body stacked on the composite substrate. The characteristics of the device are ensured by specifying the dislocation density of the nitride semiconductor layer of the composite substrate.

### Citation List

### Patent Literature

PTL 1: Japanese Patent No. 5407385

### SUMMARY OF INVENTION

### Technical Problem

Examples of substrates for crystal growth include sapphire substrates, SiC (silicon carbide) substrates, and Si substrates. When a Si substrate is used as the substrate of the above conventional nitride semiconductor device and then a GaN layer, for example, is grown on the Si substrate, the Si substrate is damaged by stress caused by the difference in lattice constant between the Si substrate and the GaN layer and the difference in thermal expansion coefficient therebetween. Therefore, when the Si substrate is used as the substrate of the above conventional nitride semiconductor device, the characteristics of the device cannot be ensured sufficiently by simply specifying the dislocation density of the nitride semiconductor layer and the dislocation density of the bonding layer to ensure their crystallinity.

Accordingly, it is an object of the present invention to provide a nitride semiconductor that uses a Si substrate and can have excellent device characteristics as, for example, a nitride semiconductor device and to provide a method for manufacturing the nitride semiconductor.

### Solution to Problem

To achieve the above object, the nitride semiconductor of the present invention includes a Si substrate and a nitride semiconductor stacked body stacked on the Si substrate,

wherein the half value width of an X-ray diffraction rocking curve of the Si substrate is less than 160 arcsec.

### Advantageous Effects of Invention

In the nitride semiconductor of the present invention, the half value width (full width at half maximum) of the X-ray diffraction rocking curve of the Si substrate is less than 160 arcsec, and the Si substrate can have good crystallinity. This can reduce the damage to the Si substrate caused by the difference in lattice constant between the Si substrate and the nitride semiconductor stacked body and the difference in thermal expansion coefficient therebetween. In this case, the number of defects such as dislocations and slips is reduced, so that the nitride semiconductor obtained using the Si substrate can have excellent device characteristics as, for example, a nitride semiconductor device.

### BRIEF DESCRIPTION OF DRAWINGS

FIG. 1 is a schematic cross-sectional view of a nitride semiconductor device according to a first embodiment of the nitride semiconductor of the present invention.

FIG. 2 is a schematic cross-sectional view of part of a superlattice buffer layer of the nitride semiconductor device in FIG. 1.

### DESCRIPTION OF EMBODIMENTS

### First Embodiment

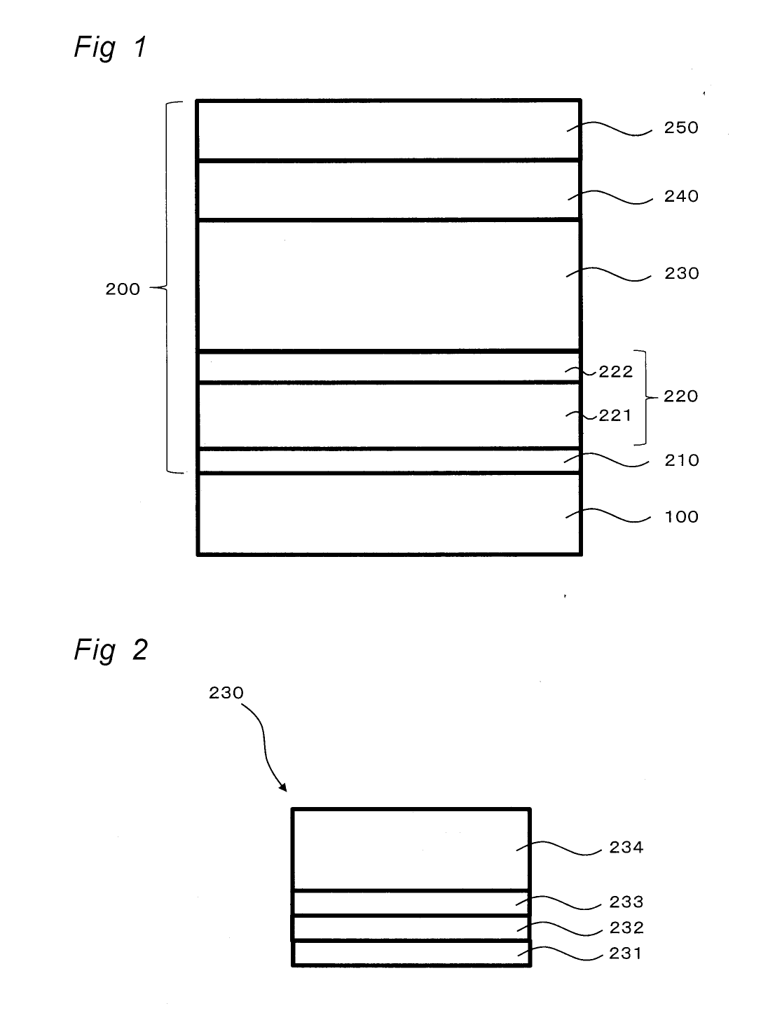

As shown in FIG. 1, a nitride semiconductor device according to a first embodiment of the nitride semiconductor of the present invention is a high electron mobility transistor (HEMT) including a Si substrate 100 and a nitride semiconductor stacked body 200. In FIG. 1, electrodes etc. are omitted for the sake of convenience of description.

In the Si substrate 100, its (111) plane serves as the principal surface. The principal surface of the Si substrate 100 is not limited to the (111) plane and may be a (000) plane.

The nitride semiconductor stacked body 200 is disposed on the principal surface of the Si substrate 100 and includes an AlN layer 210, an AlGaN buffer layer 220, a superlattice buffer layer 230, an undoped GaN layer 240, and an AlGaN barrier layer 250. The AlN layer 210, the AlGaN buffer layer 220, the superlattice buffer layer 230, the undoped GaN layer 240, and the AlGaN barrier layer 250 are examples of the nitride semiconductor layer.

The AlGaN buffer layer 220 includes an Al_{0.50}Ga_{0.50}N layer 221 and a GaN layer 222. As shown in FIG. 2, the superlattice buffer layer 230 includes an AlN layer 231, an Al_{0.03}Ga_{0.97}N layer 232, an Al_{0.05}Ga_{0.95}N layer 233, and an Al_{0.07}Ga_{0.93}layer 234.

### [Manufacturing Method]

Next, an example of a method for manufacturing the nitride semiconductor device in the first embodiment will be described.

First, a Si substrate 100 with a thickness of 800 μm with its (111) plane serving as the principal surface is treated with diluted fluorine before the growth of the nitride semiconductor stacked body 200 to remove a natural oxide film on the Si substrate 100.

Then the Si substrate 100 with the natural oxide film removed is introduced into a reactor of an MOCVD (Metal Organic Chemical Vapor Deposition) device. After the introduction of the Si substrate 100 into the reactor of the MOCVD device, the substrate temperature of the Si substrate 100 is increased from room temperature to 1,100° C., and H₂ (hydrogen), N₂ (nitrogen), NH₃ (ammonia), and TMA (trimethylaluminum) are supplied to the reactor of the MOCVD device. An AlN layer 210 with a thickness of 150 nm is thereby grown on the principal surface of the Si substrate 100.

Next, the substrate temperature of the Si substrate 100 is changed to 1,050° C., and H₂, N₂, NH₃, TMA, and TMG (trimethylgallium) are supplied to the reactor of the MOCVD device to grow an AlGaN buffer layer 220 on the AlN layer 210. The AlGaN buffer layer 220 is produced by growing an Al_{0.50}Ga_{0.50}N layer 221 with a thickness of 300 nm on the AlN layer 210 and then growing a GaN layer 222 with a thickness of 20 nm on the Al_{0.50}Ga_{0.50}N layer 221.

Then, while the substrate temperature of the Si substrate 100 is held at 1,050° C., a superlattice buffer layer 230 is grown on the AlGaN buffer layer 220. The superlattice buffer layer 230 is produced by repeating the following steps (1) to (4) 60 times.

(1) H₂, N₂, NH₃, and TMA are supplied to the reactor of the MOCVD device to grow an AlN layer 231 with a thickness of 3.5 nm on the AlGaN buffer layer 220 (on an Al_{0.07}Ga_{0.93}N layer 234 in the second and subsequent repetitions).

(2) H₂, N₂, NH₃, TMA, and TMG are supplied to the reactor of the MOCVD device to grow an Al_{0.03}Ga_{0.97}N layer 232 with a thickness of 1.5 nm on the AlN layer 231.

(3) H₂, N₂, NH₃, TMA, and TMG are supplied to the reactor of the MOCVD device to grow an Al_{0.05}Ga_{0.95}N layer 233 with a thickness of 1.5 nm on the Al_{0.03}Ga_{0.97}N layer 232.

(4) H₂, N₂, NH₃, TMA, and TMG are supplied to the reactor of the MOCVD device to grow an Al_{0.07}Ga_{0.93}N layer 234 with a thickness of 23.5 nm on the Al_{0.05}Ga_{0.95}N layer 233.

Then, while the substrate temperature of the Si substrate 100 is held at 1,050° C., H₂, N₂, NH₃, and TMG are supplied to the reactor of the MOCVD device to grow an undoped GaN layer 240 with a thickness of 1,200 nm on the superlattice buffer layer 230.

Then, while the growth temperature is held at 1,050° C., H₂, N₂, NH₃, TMA, and TMG are supplied to the reactor of the MOCVD device to grow an AlGaN barrier layer 250 on the undoped GaN layer 240. The AlGaN barrier layer 250 is produced by growing Al_{0.15}Ga_{0.85}N to a thickness of 30.0 nm on the undoped GaN layer 240.

Through the manufacturing steps described above, the nitride semiconductor stacked body 200 having a nitride semiconductor epitaxy structure including the AlN layer 210, the AlGaN buffer layer 220, the superlattice buffer layer 230, the undoped GaN layer 240, and the AlGaN barrier layer 250 stacked in this order on the Si (111) substrate 100 is obtained. Electrodes, insulating films, etc. are formed on the nitride semiconductor stacked body 200 using a photo lithographic technique. Then the Si substrate 100 is subjected to manufacturing steps such as grinding, polishing, dicing, die bonding, and mounting, whereby an HEMT device including the Si substrate 100 with a thickness of 85 μm is manufactured.

### [X-ray Diffraction]

An ω scan was performed using an X-ray diffraction (XRD) apparatus to examine the full width at half maximum (FWHM) of an X-ray diffraction rocking curve of the Si substrate 100.

The crystallinity of the Si substrate 100 varies significantly due to the influence of heat after the crystal growth by MOCVD. The degree of the influence depends on the thickness and size of the Si substrate 100, the growth temperature, the rate of temperature increase, and the rate of temperature decrease. In this case, attention was given to the rate of increase in the temperature of the Si substrate 100. Specifically, studies were conducted on Si substrates 100 produced using different rates of increase in temperature from room temperature to 1,100° C. The Si substrates 100 were divided into the following 8 groups A to H based on the FWHM results of the w scan of the Si (111).

(A) less than 40 arcsec

(B) 40 arcsec or more and less than 70 arcsec

(C) 70 arcsec or more and less than 100 arcsec

(D) 100 arcsec or more and less than 130 arcsec

(E) 130 arcsec or more and less than 160 arcsec

(F) 160 arcsec or more and less than 190 arcsec

(G) 190 arcsec or more and less than 220 arcsec

(H) 220 arcsec or more

A high temperature reverse bias (HTRB) test for drain-source ON-resistance (RdsON) at 150° C. and drain current when the gate-source voltage was 0 V (Idss) was performed. The yield in terms of the (RdsON) and the (Idss) after a lapse of 500 hours was as follows.

(A) 83.9% on average

(B) 72.6% on average

(C) 68.7% on average

(D) 62.5% on average

(E) 59.6% on average

(F) 20.8% on average

(G) 14.3% on average

(H) 8.7% on average

As can be seen from the above results, when the FWHM was less than 160 arcsec (A to E), the crystallinity was good, and the number of defects in the Si substrate 100 was small, so that the yield was good.

Specifically, when the half value width (full width at half maximum) of the X-ray diffraction rocking curve of the Si substrate 100 is less than 160 arcsec, the crystallinity of the Si substrate 100 is good. In this case, damage to the Si substrate 100 caused by the difference in lattice constant between the Si substrate 100 and the nitride semiconductor stacked body 200 and the difference in thermal expansion coefficient therebetween can be reduced. Therefore, the number of defects such as dislocations and slips formed in the Si substrate 100 can be reduced, and the nitride semiconductor device obtained using the Si substrate can have excellent device characteristics.

As can be seen, when the FWHM was 160 arcsec or more (F to H), the number of defects in the Si substrate 100 was large, and its yield was poor.

When the FWHM is 160 arcsec or more (F to H), i.e., when the value of the ω scan is not good, it is highly possible that defects such as dislocations and slips are generated in the Si substrate 100 with the HEMT structure grown thereon mainly during the crystal growth by MOCVD. The defects generated in the Si substrate 100 may propagate not only through the Si substrate 100 but also into the nitride semiconductor stacked body 200 and increase in number due to thermal damage and electric damage to the Si substrate 100 during the steps of preparing a device using the Si substrate 100 with the HEMT structure grown thereon and the HTRB test conducted thereafter. In this case, the undoped GaN layer 240 and the vicinity of the AlGaN barrier layer 250 are affected, and this causes deterioration in the variability characteristics of the ON resistance and deterioration in the drain current characteristics.

Preferably, an AlₓGa₁₋ₓN (0.80<x≦1) layer with a thickness of 30 nm or more is stacked on the Si substrate 100. This is because, when x is 0.80 or less, the content of Ga exceeds 20%. In this case, Si reacts with Ga, and defects such as pits are generated in the nitride semiconductor. If the thickness of this AlₓGa_{1 x}N layer is 30 nm or less, Ga in an AlₓGa_{1 x}N layer with x equal to or less than 0.80 that is formed on the above AlₓGa_{1 x}N layer reacts with Si in the Si substrate 100 through defects such as dislocations, nanopipes, and micropipes, and this causes defects such as pits to be generated in the nitride semiconductor. In the nitride semiconductor device in the present embodiment, the AlN layer 210 with a thickness of 150 nm is stacked on the Si substrate 100 to suppress the reaction of Si and Ga.

Preferably, the thickness of the nitride semiconductor stacked body 200 on the Si substrate 100 is 2 μm or more. This is because of the following reason. When the thickness of the nitride semiconductor stacked body 200 is less than 2 μm, the distance between the Si substrate 100 and the vicinity of the interface between the undoped GaN layer 240 and the AlGaN barrier layer 250 at which a 2-dimension electron gas (2DEG) is generated is small. Therefore, when defects are generated in the Si substrate 100, the 2DEG is less likely to generate carrier due to the influence of the defects. In the nitride semiconductor device in the present embodiment, the nitride semiconductor stacked body 200 has a thickness of 3.5 μm, and this can prevent the 2DEG from being influenced by defects generated in the Si substrate 100.

The relation between the thickness of the Si substrate 100 and the yield in terms of the rate of change in the ON resistance was examined.

(Thickness of Si substrate 100):(yield)

Less than 30 μm:45.7%

30 μm or more and less than 80 μm:63.8%

80 μm or more and less than 130 μm:68.7%

130 μm or more and less than 180 μm:72.3%

180 μm or more and less than 230 μm:71.9%

230 μm or more and less than 280 μm:69.8%

280 μm or more and less than 330 μm:48.2%

330 μm or more and less than 380 μm:36.3%

As can be seen from the above results, when the thickness of the Si substrate 100 was less than 30 μm or 280 μm or more, the yield became deteriorated. This may be because of the following reasons. When the thickness of the Si substrate 100 is less than 30 μm, the Si substrate 100 is excessively thin, so that defects such as cracks are easily generated in the Si substrate 100. When the thickness of the Si substrate 100 is 280 μm or more, defects due to the influence of heat are easily generated in the Si substrate 100 because the thermal conductivity of silicon is low.

Therefore, it is preferable to process the Si substrate 100 such that it has a thickness of 30 μm or more and less than 280 nm. In this case, the Si substrate 100 obtained can resist cracking and is less susceptible to heat. Therefore, the nitride semiconductor device obtained can have high long-term reliability and a long service life.

The relation between the thickness of the Si substrate 100 before the crystal growth of the nitride semiconductor stacked body 200 and the yield in terms of cracking in the Si substrate 100 during the process for manufacturing the nitride semiconductor device was examined. A yield of 100% means that no cracking occurred in the Si substrate 100 during the process for manufacturing the nitride semiconductor device.

(Thickness of Si substrate 100 before crystal growth):(yield)

300 μm:85.8%

350 μm:99.4%

400 μm:100.0%

450 μm:100.0%

500 μm:100.0%

600 μm:100.0%

As can be seen from the above results, when the thickness of the Si substrate 100 before the crystal growth of the nitride semiconductor stacked body 200 was less than 400 μm, the yield in terms of cracking of the Si substrate 100 became deteriorated. Therefore, preferably, the thickness of the Si substrate 100 before the crystal growth of the nitride semiconductor stacked body 200 is 400 μm or more.

Preferably, the thickness of the Si substrate 100 before the crystal growth of the nitride semiconductor stacked body 200 is less than 1,600 μm. This is because, if the thickness of the Si substrate 100 before the crystal growth is 1,600 μm or more, the cost of the Si substrate 100 itself becomes high.

Therefore, when the thickness of the Si substrate 100 used is 400 μm or more and less than 1,600 μm before the crystal growth of the nitride semiconductor stacked body 200, the nitride semiconductor device can be manufactured at low cost.

Preferably, the half value width (full width at half maximum) of the (002) X-ray diffraction rocking curve of the AlN layer 210 of the Si substrate 100 is 800 arcsec or more and less than 2,000 arcsec. This is because of the following reasons. When the half value width of the (002) X-ray diffraction rocking curve of the AlN layer 210 is less than 800 arcsec, the crystallinity of the AlN layer 210 is excessively good. In this case, the warpage of the Si substrate 100 after the crystal growth of the nitride semiconductor stacked body 200 becomes excessively large. When the half value width of the (002) X-ray diffraction rocking curve of the AlN layer 210 is 2,000 arcsec or more, the crystallinity of the nitride semiconductor layer stacked on the AlN layer 210 deteriorates, and this causes an increase in the number of defects in the Si substrate 100. Therefore, electrical leakage increases, and the device characteristics of the nitride semiconductor device deteriorate.

### Second to Sixth Embodiments

A nitride semiconductor device in another embodiment of the nitride semiconductor of the present invention is not limited to the HEMT in the first embodiment and may be, for example, a metal-insulator-semiconductor field effect transistor (MISFET) (a second embodiment), a junction FET (a third embodiment), an LED (a light-emitting diode) (a fourth embodiment), or a semiconductor laser (a fifth embodiment).

The nitride semiconductor of the present invention is not limited to the nitride semiconductor devices in the first to fifth embodiments and is intended to encompass, for example, a nitride semiconductor epitaxial wafer for the nitride semiconductor devices in the first to fifth embodiments each including the Si substrate 100 and the nitride semiconductor stacked body 200 (a sixth embodiment).

The present invention and the embodiments are summarized as follows.

The nitride semiconductor of the present invention includes:

the Si substrate 100; and the nitride semiconductor stacked body 200 stacked on the Si substrate 100,

wherein the half value width of the X-ray diffraction rocking curve of the Si substrate 100 is less than 160 arcsec.

In the nitride semiconductor of the present invention, since the half value width of the X-ray diffraction rocking curve of the Si substrate 100 is less than 160 arcsec, the Si substrate 100 can have good crystallinity. This allows damage to the Si substrate 100 caused by the difference in lattice constant between the Si substrate 100 and the nitride semiconductor stacked body 200 and the difference in thermal expansion coefficient therebetween to be reduced. Therefore, the number of defects such as dislocations and slips generated in the Si substrate 100 can be reduced, so that the nitride semiconductor obtained using the Si substrate can have excellent device characteristics as, for example, a nitride semiconductor device.

In one embodiment of the nitride semiconductor,

the nitride semiconductor stacked body 200 includes an AlₓGa₁₋ₓN (0.80<x≦1) layer 210 in contact with the Si substrate 100 and having a thickness of 30 nm or more.

In the above embodiment, the reaction of Si in the Si substrate 100 with Ga in the AlₓGa₁₋ₓN (0.80<x≦1) layer 210 can be suppressed. This allows damage to the Si substrate 100 caused by the difference in lattice constant between the Si substrate 100 and the nitride semiconductor stacked body 200 and the difference in thermal expansion coefficient therebetween to be reduced. Therefore, the number of defects such as dislocations and slips generated in the Si substrate 100 can be reduced, so that the nitride semiconductor obtained using the Si substrate can have excellent device characteristics as, for example, a nitride semiconductor device.

In another embodiment of the nitride semiconductor,

the nitride semiconductor stacked body 200 has a thickness of 2 μm or more.

In the above embodiment, the region of the nitride semiconductor stacked body 200 in which a two-dimensional electron gas is formed is separated sufficiently from the Si substrate 100, so that, even when defects such as slips are generated in the Si substrate 100, the two-dimensional electron gas is less likely to be influenced by the defects. Therefore, the nitride semiconductor obtained using the Si substrate can have excellent device characteristics as, for example, a nitride semiconductor device.

In another embodiment of the nitride semiconductor, the nitride semiconductor is a high electron mobility transistor.

In the above embodiment, the nitride semiconductor obtained has high electron mobility.

In another embodiment of the nitride semiconductor,

the (111) plane or (000) plane of the Si substrate 100 serves as its principal surface in contact with the nitride semiconductor stacked body 200.

In the above embodiment, the (111) plane or (000) plane with good crystallinity is the principal surface in contact with the nitride semiconductor stacked body 200. This allows damage to the Si substrate 100 caused by the difference in lattice constant between the Si substrate 100 and the nitride semiconductor stacked body 200 and the difference in thermal expansion coefficient therebetween to be reduced. Therefore, the number of defects such as dislocations and slips generated in the Si substrate 100 can be reduced, so that the nitride semiconductor obtained using the Si substrate can have excellent device characteristics as, for example, a nitride semiconductor device.

In another embodiment, the nitride semiconductor has a thickness of 30 μm or more and less than 280 μm.

In the above embodiment, the Si substrate 100 obtained resists cracking etc. and is less susceptible to heat. Therefore, the nitride semiconductor obtained can have high long-term reliability and a long service life.

In the method for manufacturing the nitride semiconductor of the present invention, the nitride semiconductor stacked body 200 includes the AlN layer 210 disposed on the Si substrate 100, and

the half value width of the (002) X-ray diffraction rocking curve of the AlN layer 210 is 800 arcsec or more and less than 2,000 arcsec.

According to the manufacturing method of the present invention, a nitride semiconductor device in which the crystallinity of the Si substrate 100 is not excessively good and not excessively poor can be obtained. Therefore, for example, a nitride semiconductor device having excellent device characteristics can be obtained using the Si substrate.

In one embodiment of the method for manufacturing the nitride semiconductor,

the thickness of the Si substrate 100 before crystal growth of the nitride semiconductor stacked body 200 is 350 μm or more and less than 1,600 μm.

In the above embodiment, cracking of the Si substrate 100 during the steps of manufacturing the nitride semiconductor can be prevented, and the cost of the Si substrate 100 itself can be reduced. Therefore, the nitride semiconductor can be manufactured at low cost.

### REFERENCE SIGNS LIST

100 Si substrate

200 nitride semiconductor stacked body

210 AlN layer

220 AlGaN buffer layer

221 Al_{0.50}Ga_{0.50}N layer

222 GaN layer

230 superlattice buffer layer

231 AlN layer

232 Al_{0.03}Ga_{0.97}N layer

233 Al_{0.05}Ga_{0.95}N layer

234 Al_{0.07}Ga_{0.93}N layer

240 undoped GaN layer

250 AlGaN barrier layer

1-5. (canceled)

6. A nitride semiconductor comprising: a Si substrate; and a nitride semiconductor stacked body disposed on the Si substrate,
wherein a half value width of an X-ray diffraction rocking curve of the Si substrate is less than 160 arcsec.

7. The nitride semiconductor according to claim 6, wherein the nitride semiconductor stacked body includes an AlₓGa₁₋ₓN (0.80<x≦1) layer in contact with the Si substrate and having a thickness of 30 nm or more.

8. The nitride semiconductor according to claim 6, wherein the nitride semiconductor stacked body has a thickness of 2 μm or more.

9. The nitride semiconductor according to claim 6, wherein the nitride semiconductor has a thickness of 30 μm or more and less than 280 μm.

10. A method for manufacturing the nitride semiconductor according to claim 6,
wherein the nitride semiconductor stacked body includes an AlN layer disposed on the Si substrate, and
a half value width of a (002) X-ray diffraction rocking curve of the AlN layer is 800 arcsec or more and less than 2,000 arcsec.
